(19) United States
(12) Patent Application Publication
(10) Pub. No.: US 2013/0169125 A1
(43) Pub. Date: Jul. 4, 2013

(54) CORNER IMPROVEMENT IN WINDOW CARRIER FOR CRACK WINDOW

(71) Applicant: Sony Ericsson Mobile Communications AB, Lund (SE)

(72) Inventor: Daniel KRISTENSSON, Saxtorp (SE)

(73) Assignee: SONY ERICSSON MOBILE COMMUNICATIONS AB, Lund (SE)

(21) Appl. No.: 13/677,350

(22) Filed: Nov. 15, 2012

Related U.S. Application Data
(60) Provisional application No. 61/581,725, filed on Dec. 30, 2011.

(30) Foreign Application Priority Data
Dec. 30, 2011 (EP) PCT/EP2012/063432

(51) Int. Cl. H05K 5/03; H05K 13/04

(52) U.S. Cl. CPC H05K 5/03; H05K 13/04
USPC 312/223.1; 29/592.1

(57) ABSTRACT

A protective arrangement for a mobile device comprising a protective frame and a display arranged at a distance from each other. The display having a front display surface, a display side and a display edge between the front display surface and the display side, were the protective frame being adapted to deform, by means of a ledge and a ridge, when a shock force is applied to the protective frame. The ledge is positioned closer to the display compared to the ridge and the ledge is flush with or below the front display surface such that pinching of the display edge is eliminated when the protective frame is deformed.

### TECHNICAL FIELD

The invention relates in general to the field of shock proofing of mobile communication devices, and more particularly, for improving the durability of the mobile communication device display when the casing of the mobile communication device is subjected to an external shock force such as the force from a drop.

### BACKGROUND

It is a well known fact that if a mobile communication device such as a mobile phone is dropped from a height, for instance from chest height of an average person, the display is often cracked, especially in the corners. Thus, finding a way to increase the durability of the mobile communication device and thus reduce the risk of cracking the display when dropped is therefore highly sought after.

### SUMMARY OF THE INVENTION

With the above description in mind, then, an aspect of the present invention is to provide a way to increase the durability of the mobile communication device (or mobile device), hereinafter referred to as a mobile phone, and thus reduces the likelihood of cracking the display, especially in the corner, when dropped.

The object of the present invention relates to a protective arrangement for a mobile phone which has a protective frame and a display arranged at a distance, c, from each other. The display has a front display surface, a display side and a display edge between the front display surface and the display side.

A first aspect of the present invention relates to a protective arrangement for a mobile phone with a protective frame which is adapted to deform when a shock force is applied onto the protective frame, by means of a ledge and a ridge. The ledge is positioned closer to the display compared to the ridge and the ledge is flush with or below the front display surface for eliminating pinching of the display edge in response to the shock force. The effect of that the ledge is flush with or below the front display surface is that when a shock force is applied to the protective frame, for example if the mobile phone is dropped and hits the ground somewhere on the protective frame, the protective frame will not deform so that it applies pressure on the front display surface; the deformed protective frame will only apply pressure on the display side. The ridge is placed on the opposite side of the protective frame from the ledge. It is positioned at a distance from the display so that it will not apply pressure on the front display surface upon deformation from an applied shock force on the protective frame. The ridge is also higher than the front display surface so that if the mobile phone is dropped with the front display surface facing downwards, it lands on the ridge and not the display.

The protective arrangement may further comprise that the display comprises, singularly or in any combination, any of the following: a glass, plastic and ASF (Anti Shatter Film). I.e. the display can be made of glass with an ASF on it, of plastic with an ASF on it or a combination of glass and plastic with an ASF on it.

The protective arrangement may further comprise that the protective frame is made of a deformable material, such as plastic, rubber, metal or a combination thereof. If the mobile phone is dropped and hits something hard, a deformable protective frame will absorb some of the shock from the impact and in so doing protect the mobile phone.

The protective arrangement may further comprise that the distance c is at least 0.1 mm wide. The distance is a necessity in producing the mobile phone and it also protects the display to a degree from breaking if the mobile phone is dropped.

The protective arrangement may further comprise that the width of the ledge is at least as large as the distance, c. The ledge has to have some width to protect the display.

The protective arrangement may further comprise that the width of the ledge is between 5% and 95% of the width of the protective frame. A large variety of widths of the ledge will function to protect the display from breaking; smaller widths protect from smaller shock forces and larger widths protect the display at both smaller and larger shock forces.

The protective arrangement may further comprise that the width of the ledge is at least a quarter of the width of the protective frame.

The protective arrangement may further comprise that the width of the ledge is at least half the width of the protective frame.

The protective arrangement may further comprise that the display edge either has a rounded shape or a sharp or chamfered corner. Different shapes of the corner have different properties and the corner shape can be chosen depending on the width of the ledge and the height of the ridge to optimize the prevention of breaking the display upon shock force applied to the protective frame.

The protective arrangement may further comprise that the ridge is higher than the ledge and the height of the ridge is smaller the narrower the ledge. The ridge is higher than the ledge to protect the display in the case where the mobile phone is dropped with the display facing directly downwards. The narrower the ledge the smaller can the height of the ridge be; upon shock impact on the upper, outer side of the ridge of the protective frame the frame is deformed inwards and downwards towards the ledge, so the ridge should not be so high that it deforms over the ledge and applies pressure on the front display surface.

A second aspect of the present invention relates to a method for producing a protective arrangement for a mobile phone with the steps of:

Arranging a protective frame and a display at a distance c from each other, where the display has a front display surface, a display side and a display edge between the front display surface and the display side,
adapting the protective frame to deform when a shock force is applied to the protective frame,
adding a ridge to the protective frame so that the protective frame forms a ledge and a ridge, wherein the ledge is positioned closer to the display compared to the ridge,
arranging the ledge so that it is flush with or below the front display surface such that pinching of the display edge is eliminated in response to the shock force applied to the protective frame.

The method for producing a protective arrangement comprises that the protective frame and the display are arranged at a distance c from each other because of manufacturing limitations and because it protects the display from breaking when small shock forces are applied to the protective frame. The protective frame deforms upon shock force to absorb the shock to protect the display. The ridge is placed on the opposite side of the protective frame from the ledge. It is positioned at a distance from the display so that it will not apply pressure on the front display surface upon deformation from an applied shock force on the protective frame. The effect of that the ledge is flush with or below the front display surface is that when a shock force is applied to the protective frame, for example if the mobile phone is dropped and hits the ground somewhere on the protective frame, the protective frame will not deform so that it applies pressure on the front display surface; the deformed protective frame will only apply pressure on the display side. The ridge is also higher than the front display surface so that if the mobile phone is dropped with the front display surface facing downwards, it lands on the ridge and not the display.

### BRIEF DESCRIPTION OF THE DRAWINGS

Further objects, features, and advantages of the present invention will appear from the following detailed description of some embodiments of the invention, wherein some embodiments of the invention will be described in more detail with reference to the accompanying drawings, in which:

FIG. 1 shows the ordinary design of the plastic edge according to prior art;

FIG. 2 shows the corner pinching of the plastic protective edge which will result in a cracked display according to prior art; and

FIG. 3 shows a cross section view of a protective arrangement in a mobile phone where the width b of the ledge 304 is larger than the width e of the ridge 305 and where the distance a between the front display surface 303 and the ledge in the protective frame 307 is such that the ledge 304 is situated on the same level as the front display surface 303. Further are the distances d and c arbitrary; and

FIG. 4 shows a cross section view of a protective arrangement in a mobile phone where the width b of the ledge 404 is smaller than the width e of the ridge 405 and where the distance a between the front display surface 403 and the ledge in the protective frame 407 is such that the ledge is situated on the same level as the front display surface 403. Further are the distances d and c arbitrary; and

FIG. 5 shows a cross section view of a protective arrangement in a mobile phone where the width b of the ledge 504 is larger than the width e of the ridge 505 and where the distance a between the front display surface 503 and the ledge in the protective frame 507 is such that the ledge is situated below the front display surface 503. Further are the distances d and c arbitrary; and

FIG. 6 shows a cross section view of a protective arrangement in a mobile phone where the width b of the ledge 604 is smaller than the width e of the ridge 605 and where the distance a between the front display surface 603 and the ledge in the protective frame 607 is such that the ledge is situated below the front display surface 603. Further are the distances d and c arbitrary; and

FIG. 7 shows a cross section view of the deformation of the ledge 704 during an impact on the edge of a mobile phone where the width b of the ledge is equal to the width e of the ridge 705 and where the distance a between the front display surface 703 and the ledge in the protective frame 707 is such that the ledge is situated above the front display surface 703; and

FIG. 8 shows a cross section view of the deformation of the ledge 804 during an impact on the edge of a mobile phone where the width b of the ledge is equal to the width e of the ridge 805 and where the distance a between the front display surface 803 and the ledge in the protective frame 807 is such that the ledge is situated on the same level as the front display surface 803; and

FIG. 9 shows a cross section view of the deformation of the ledge 904 during an impact on the edge of a mobile phone where the width b of the ledge is equal to the width e of the ridge 905 and where the distance a between the front display surface 903 and the ledge in the protective frame 907 is such that the ledge is situated below the front display surface 903; and

FIG. 10 shows an above view of a corner of a mobile phone where the radius f of the display, the width b of the ledge 1004, the width e of the ridge 1005 and the gap c between the front display surface 1003 and the ledge can vary independently of each other; and

FIG. 11 shows present invention and that a force applied to the protective frame will not result in a pinched display edge.

### DETAILED DESCRIPTION

Embodiments of the present invention will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art.

Embodiments of the present invention will be exemplified using a mobile communication device such as a mobile phone. However, it should be appreciated that the invention is as such equally applicable to electronic devices in general which have a display which may be made of a material that breaks easily if dropped. Examples of such devices may for instance be any type of mobile phone, laptops (such as standard, ultra portables, netbooks, micro laptops, and pads), handheld computers, PDAs, gaming devices, accessories to mobile phones, etc. However, for the sake of clarity and simplicity, the embodiments outlined in this specification are only exemplified with and related to mobile communication devices (or mobile devices) hereinafter referred to as mobile phones.

The display in mobile phones is normally very sensitive to shock forces which are applied when the mobile phone is dropped and is therefore often protected by a frame around the edge and side of the mobile phone. The more shock absorbing the material of the frame is, the better protection of the display. To get the desired shock absorption, the edge of the frame is often thick and bulky and this often goes against how the designer would design the mobile phone. The designer would often like to have an as sleek look and esthetic look as possible so there is a conflict between protecting the mobile phone and getting the desired look. But even though the edge of the frame is made thicker and bulkier in the corners it might not be enough to protect the display when the mobile phone is dropped. Therefore there is a need for an arrangement which protects the mobile phone upon shock forces which does not require the frame to be made thicker and bulkier. When a shock force is applied to the frame the display is often cracked by the deformed material of the frame. Thus, avoiding this pinching effect would make a mobile phone less sensitive to shock forces.

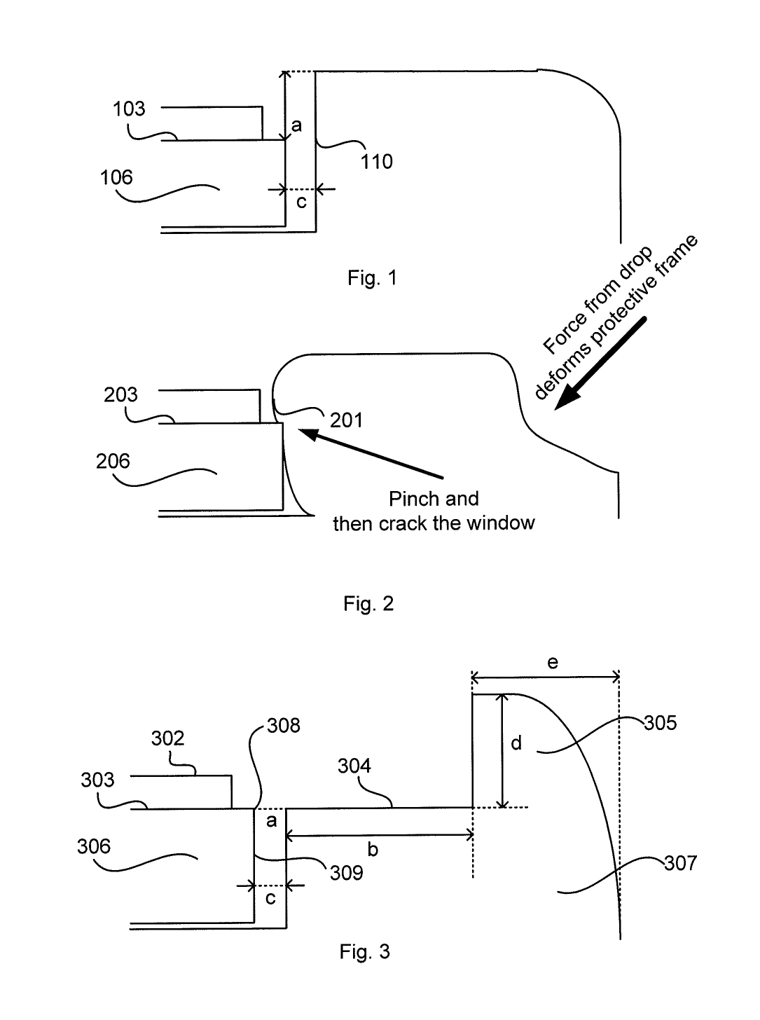

FIG. 1 shows a typical plastic protection frame around the display according to prior art. In the prior art the height of the edge 110 closest to the display is far above (the distance ‘a’ is large) the front display surface 103. A typical situation when a mobile phone is dropped from a height, thus subject to a shock force, onto the corner of the protection frame around the display is shown in FIG. 2. As can be seen, the protection frame around the display will be deformed on the corner where the shock force from the drop is applied, which will lead to that the edge 201 closest to the display 206 is deformed onto the front display surface 203. The deformation 201 will pinch the display resulting in a force applied to the sensitive display edge which results in a corner crack.

One way of decreasing the likelihood of cracking the display 306, 406, 506, 606, 706, 806, 906, 1106 when dropped is to, according to an embodiment of the present invention, adapt the protective frame 307, 407, 507, 607, 707, 807, 907, 1007, 1107 to deform, by means of a ledge 304, 404, 504, 604, 704, 804, 904, 1004, 1104 and a ridge 305, 405, 505, 605, 705, 805, 905, 1005, 1105, when a shock force is applied to the protective frame. By adding a ledge and a ridge to the protective frame, tests have shown that stresses can be decreased in the display by 11% or more generally by 10-20%. This solution is also preferred by the designer compared to a thicker frame without a ledge and a ridge.

FIGS. 3-6 show different aspects and design options of the protective frame 307, 407, 507, 607 around the display 306, 406, 506, 606 according to the present invention. As can be seen in the figures the ledge 304, 404, 504, 604 is positioned closer to the display compared to the ridge 305, 405, 505, 605 and the ledge is flush with or below the front display surface 303, 403, 503, 603 such that pinching of the display edge 308, 408, 508, 608 is eliminated in response to the shock force. Pinching of the display edge comprises that the protective frame 307, 407, 507, 607 applies pressure on both the front display surface and the display side 309, 409, 509, 609 when deformed by a force applied onto the protective frame; i.e. the pinching occurs around the display edge.

FIGS. 3 and 5 shows a cross section view of a protective arrangement in a mobile phone where the width b of the ledge 304, 504 is larger than the width e of the ridge 305, 505 and where the distance a between the front display surface 303, 503 and the ledge in the protective frame 307, 507 is such that the ledge is situated on the same level or below the front display surface. When b is larger than e, as illustrated, it is not possible for the ridge to deform so that it applies pressure on the front display surface 103 because it is not close enough.

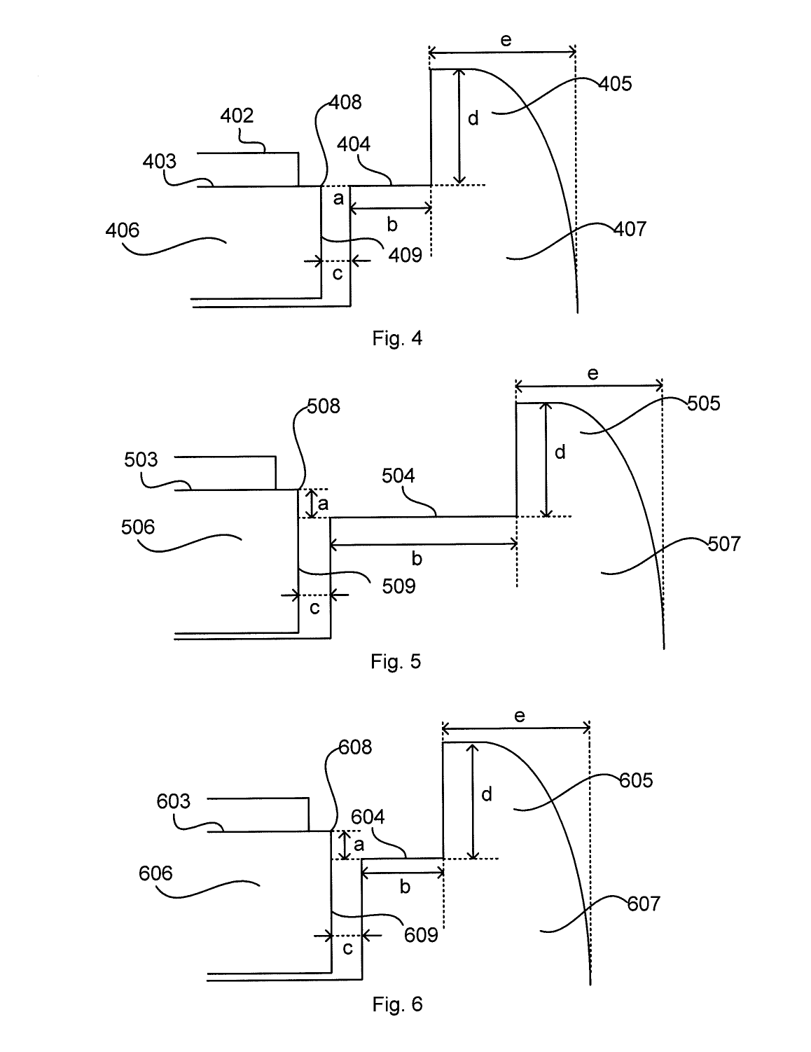

FIGS. 4 and 6 shows a cross section view of a protective arrangement in a mobile phone where the width b of the ledge 404, 604 is smaller than the width e of the ridge 405, 605 and where the distance a between the front display surface 403, 603 and the ledge in the protective frame 407, 607 is such that the ledge is situated on the same level or below the front display surface. When b is much smaller than e and d is higher than b is wide, it is possible, upon sufficient shock force applied to the protective frame, to deform the ridge so that it applies pressure on the front display surface. This arrangement protects the display 406, 606 against shock forces but the proportions of the width of the ledge and the width and height of the ridge must be considered thoroughly depending on how big shock forces the mobile phone has to be able to take.

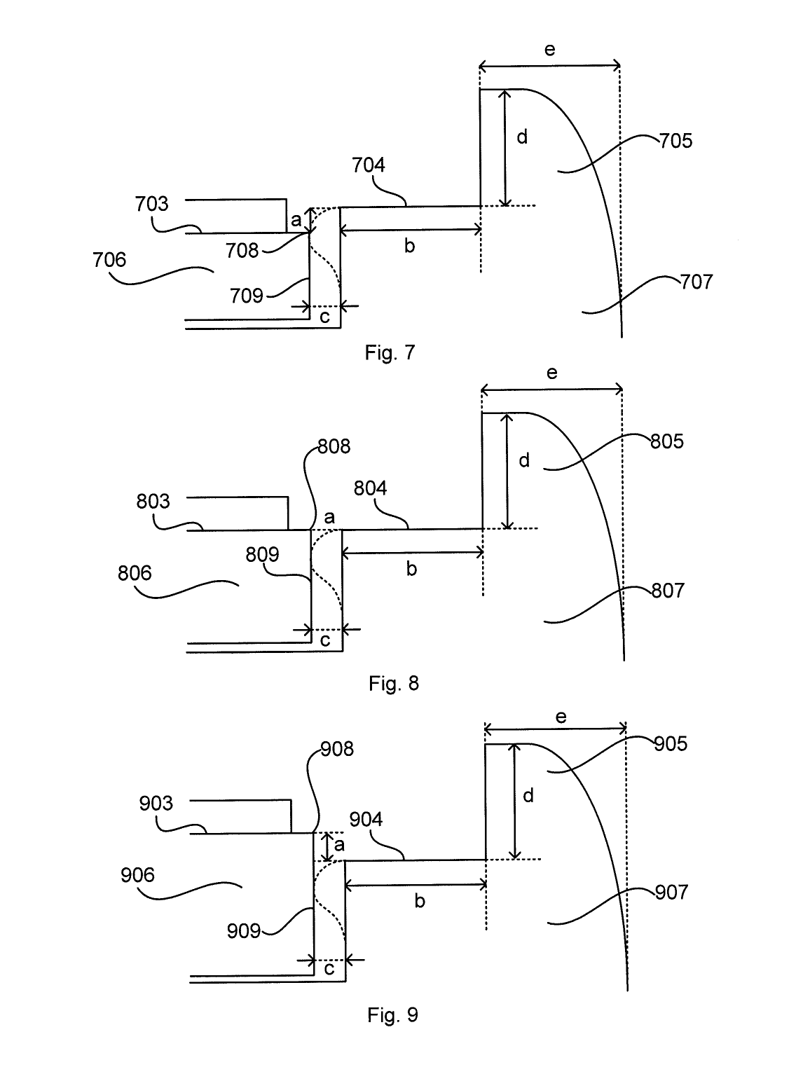

FIGS. 7-9 illustrate the deformation of the ledge 704, 804, 904 of the protective frame 707, 807, 907 at different levels of the ledge. In FIG. 7 the ledge is higher than the front display surface 703 so the deformation of the protective frame applies pressure on both the display side 709 and the front display surface; i.e. the deformed protective frame pinches the display edge 708. In FIGS. 8 and 9 the ledge 804, 904 is level with, or flush with, or below the front display surface 803, 903 so that the deformation of the protective frame only applies pressure on the display side 809, 909.

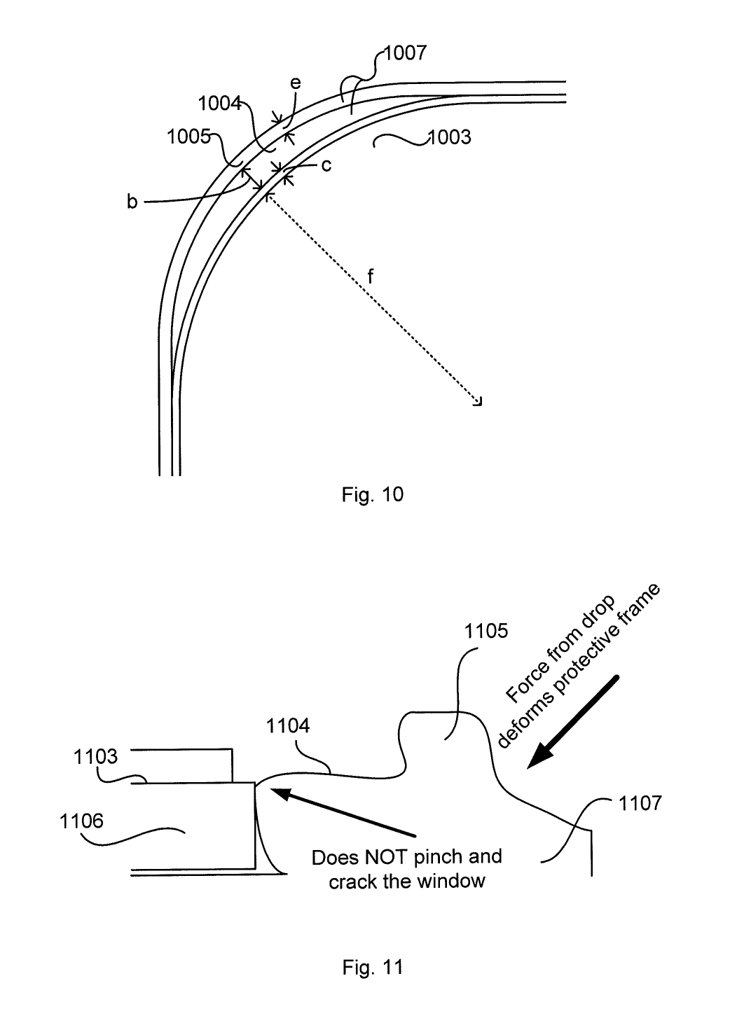

FIG. 10 shows an above view of a corner of a mobile phone where the radius f of the display, the width b of the ledge 1004, the width e of the ridge 1005 and the gap c between the display 1003 and the protective frame 1007 can vary independently of each other. In the figure there is only a ledge in the corner of the mobile phone but there can also be a ledge the whole way around the display. The ledge and ridge of the protective frame will protect the display where ever they are positioned along the protective frame and they are especially effective at the corners since it is there that the risk of cracking the display when the mobile phone is dropped is the greatest.

FIG. 11 shows the present invention wherein the ledge 1104 and the ridge 1105 have been formed on the protective frame 1107 around the display 1106 so that the pinching will not appear. When a shock force from a drop deforms the protective frame 1107 only a small force will be applied to the side of the display and no force will be applied to the front display surface 1103 and around the display edge. Thus, avoiding the occurring of pinching which may break the display.

The display 306, 406, 506, 606, 706, 806, 906, 1106 is made of glass, plastic and an ASF 302, 402, either singularly or in combination; it can be made of only glass, only rubber, glass with an ASF, plastic with an ASF or a combination of glass and plastic with an ASF. The display can be made of any material that functions as a touch sensitive display.

The protective frame 307, 407, 507, 607, 707, 807, 907, 1007, 1107 around the display 306, 406, 506, 606, 706, 806, 906, 1106 may be made of a deformable material such as plastic, metal, rubber or the like (or a mix of the materials) which is commonly used in mobile phones, especially in the design of the casing.

The distance c in FIGS. 3-10 is at least 0.1 mm between the protective frame 307, 407, 507, 607, 707, 807, 907, 1007 and the display 306, 406, 506, 606, 706, 806, 906. The distance c is a gap between the display side 309, 409, 509, 609, 709, 809, 909 and the protective frame; i.e. a vertical gap between the display and the protective frame.

The width of the ledge 304, 404, 504, 604, 704, 804, 904, 1004, 1104 is at least as wide as the distance (c) and between 5% and 95% of the width of the protective frame 307, 407, 507, 607, 707, 807, 907, 1007, 1107.

In one embodiment of the present invention the width of the ledge is at least a quarter of the width of the protective frame or at least half the width of the protective frame. The width of the ledge is dimensioned so that pinching of the display edge 308, 408, 508, 608, 708, 808, 908 by the ledge or/and the ridge is avoided when deformed by a force applied onto the protective frame. Some variants of the ledge width are shown in FIGS. 3-6.

The display edge 308, 408, 508, 608, 708, 808, 908 either has a rounded shape or a sharp or chamfered corner. In FIGS. 3-11 a sharp edge is illustrated so that the display edge has a corner shape. A rounded or chamfered edge can be used to further increase the durability of the display 306, 406, 506, 606, 706, 806, 906, 1106 in the case of a shock force applied to the protective frame. The ASF edge can also have a rounded or cornered shape or the edge can be chamfered for similar reasons as the display edge. The ASF 302, 402 can also be rounded or chamfered so that it is harder for a mobile communications device user to remove it.

In FIGS. 3 and 4 embodiments where the ledge 304, 404 is level/flush with the front display surface 303, 403 are shown. FIGS. 5 and 6 show embodiments where the ledge 504, 604 is below the front display surface. The ridge 305, 405, 505, 605 is higher than the ledge 304, 404, 504, 604 and the height of the ridge is smaller the narrower the ledge; so the smaller b is, the smaller d is. This dependency is because if d is much larger than b there is a possibility that the ridge will deform over the ledge and over the display edge 308, 408, 508, 608 upon a shock force applied to the upper side of the protective frame 307, 407, 507, 607, and in so doing breaking the display 306, 406, 506, 606. As a minimum requirement, the height of the ridge is at least flush with or above the front ASF 302, 402 surface. In one embodiment of the present invention the height of the ridge is at least a quarter of the width of the protective frame to provide sufficient protection when the mobile communications device is dropped with the display facing downwards. In one embodiment the height of the ridge can also be at least half the width of the protective frame.

The method for producing this protective arrangement for a mobile phone comprises the steps of: Arranging the protective frame 307, 407, 507, 607, 707, 807, 907, 1007, 1107 and the display 306, 406, 506, 606, 706, 806, 906, 1106 at a distance c from each other, the display having a front display surface 303, 403, 503, 603, 703, 803, 903, 1003, 1103, a display side 309, 409, 509, 609, 709, 809, 909 and a display edge 308, 408, 508, 608, 708, 808, 908 between the front display surface and the display side,

adapting the protective frame to deform when a shock force is applied to the protective frame,
adding the ridge 305, 405, 505, 605, 705, 805, 905, 1005, 1105 to the protective frame so that the protective frame forms a ledge 304, 404, 504, 604, 704, 804, 904, 1004, 1104 and a ridge, wherein the ledge is positioned closer to the display compared to the ridge,
arranging the ledge so that it is flush with or below the front display surface such that pinching of the display edge is eliminated in response to the shock force applied to the protective frame.

These steps produce a protective arrangement for a mobile phone according to FIGS. 3-11 where a ledge and a ridge protect a display from cracking/breaking upon shock force applied to a protective frame. The present invention increases the durability of the mobile phone and the risk of cracking the display reduces, especially in the corner, when the mobile phone is dropped.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

The foregoing has described the principles, preferred embodiments and modes of operation of the present invention. However, the invention should be regarded as illustrative rather than restrictive, and not as being limited to the particular embodiments discussed above. The different features of the various embodiments of the invention can be combined in other combinations than those explicitly described. It should therefore be appreciated that variations may be made in those embodiments by those skilled in the art without departing from the scope of the present invention as defined by the following claims.

1. Protective arrangement for a mobile device comprising a protective frame and a display arranged at a distance (c) from each other, the display having a front display surface, a display side and a display edge between the front display surface and the display side, characterized in that
the protective frame being adapted to deform, by means of a ledge and a ridge, when a shock force is applied to the protective frame wherein the ledge is positioned closer to the display compared to the ridge and the ledge is flush with or below the front display surface such that pinching of the display edge is eliminated when the protective frame is deformed.

2. Protective arrangement for a mobile device according to claim 1, wherein the display comprises, singularly or in any combination, any of the following: a glass, plastic and ASF.

3. Protective arrangement for a mobile device according to claim 1, wherein the protective frame is made of a deformable material, such as plastic, rubber, metal or a combination thereof.

4. Protective arrangement for a mobile device according to claim 1, wherein the distance (c) is at least 0.1 mm between the protective frame and the display.

5. Protective arrangement for a mobile device according to claim 1, wherein the width of the ledge is at least as wide as the distance (c).

6. Protective arrangement for a mobile device according to claim 1, wherein the width of the ledge is between 5% and 95% of the width of the protective frame.

7. Protective arrangement for a mobile device according to claim 1, wherein the width of the ledge is at least a quarter of the width of the protective frame.

8. Protective arrangement for a mobile device according to claim 1, wherein the width of the ledge is at least half the width of the protective frame.

9. Protective arrangement for a mobile device according to claim 1, wherein the display edge either has a rounded shape or a sharp or chamfered corner.

10. Protective arrangement for a mobile device to claim 1, wherein the ridge is higher than the ledge and the height of the ridge is smaller the narrower the ledge.

11. Method for producing a protective arrangement for a mobile device comprising:
arranging a protective frame and a display at a distance (c) from each other, the display having a front display surface, a display side and a display edge between the front display surface and the display side,
adapting the protective frame to deform when a shock force is applied to the protective frame,
characterized in
adding a ridge to the protective frame so that the protective frame forms a ledge and a ridge, wherein the ledge is positioned closer to the display compared to the ridge, and
arranging the ledge so that it is flush with or below the front display surface such that pinching of the display edge is eliminated when to the protective frame deforms.
